(19) United States
(12) Patent Application Publication
(10) Pub. No.: US 2005/0253745 A1
(43) Pub. Date: Nov. 17, 2005

(54) Digital predistortion apparatus and method for a wideband power amplifier

(75) Inventors: Yoo-Seung Song, Suwon-si (KR); Jae-Hyok Lee, Seoul (KR); Seung-Hwan Lee, Seoul (KR); Ki-Hwan Hwang, Suwon-si (KR); Jae-Ho Jeon, Seongnam-si (KR); Seung-Joo Maeng, Seongnam-si (KR)

Correspondence Address: ROYLANCE, ABRAMS, BERDO & GOODMAN, L.L.P., 1300 19TH STREET, N.W., SUITE 600, WASHINGTON,, DC, 20036, US

(73) Assignee: Samsung Electronics Co., Ltd.

(21) Appl. No.: 11/126,336

(22) Filed: May 11, 2005

(30) Foreign Application Priority Data
May 11, 2004 (KR) 2004-33050

(51) Int. Cl. H03M 1/06

(52) U.S. Cl. 341/118

(57) ABSTRACT

A method and apparatus compensate for a non-linear characteristic of a wideband power amplifier in a transmitter for a communication system, which has the wideband power amplifier for amplifying a digital input signal. The method involves the steps of (a) generating an address based on the digital input signal, reading a distortion control value corresponding to the address from a look-up table, and applying the read distortion control value to the digital input signal to predistort the digital input signal; (b) frequency up-converting the predistorted signal and amplifying the frequency up-converted signal; (c) frequency down-converting the amplified signal and compensating for a delay of the frequency down-converted signal; and (d) updating a predetermined distortion control value in the look-up table to compensate for an error value generated in the power amplifier and an analog path occurring in steps (b) and (c) based on the compensated signal.

### PRIORITY

This application claims priority under 35 U.S.C. §119(a) to an application entitled “Digital Predistortion Apparatus and Method for a Wideband Power Amplifier” filed in the Korean Intellectual Property Office on May 11, 2004 and assigned Serial No. 2004-33050, the entire contents of which are incorporated herein by reference.

### BACKGROUND OF THE INVENTION

1. Field of the Invention

The present invention relates generally to a digital predistortion apparatus and method for a broadband power amplifier. More particularly, the present invention relates to a predistortion apparatus and method for linearly amplifying broadband radio frequency (RF) signals.

2. Description of the Related Art

In the typical mobile communication system using RF signals for communication, RF amplifiers are classified into a low-power, low-noise receive amplifier and a high-power transmit amplifier. In the high-power transmit amplifier, its efficiency rather than noise is considered more significant when analyzing an amplifier. A high-power amplifier (HPA) typically used in a mobile communication system to achieve high efficiency operates in the vicinity of its non-linear operating point.

In this case, an output of the amplifier includes an inter-modulation distortion (IMD) component that serves as a spurious signal not only in its in-band but also in other frequency bands. In order to delete the spurious component, a feed-forward scheme is typically used. Although the feed-forward scheme can almost perfectly cancel the spurious component, it has low amplification efficiency and needs a control signal at an RF stage, increasing the hardware size and system cost.

In the field of the mobile communication systems, research into a high-efficiency, low-cost digital predistortion (DPD) scheme is being conducted. The digital predistortion scheme calculates an inverse characteristic of nonlinearity of a non-linear amplifier at a digital stage and predistorts an input signal using the inverse characteristic, thereby insuring substantial linearity of the output signal of the nonlinear amplifier.

A system transmitter, in its RF path, up-converts an output signal of a digital-to-analog converter (DAC) into an RF transmission signal and provides the RF transmission signal to a power amplifier. In this process, the gain and phase of the RF transmission signal suffers distortion by a local oscillator (LO) used for the up-conversion and the power amplifier. The distorted signal, if it is applied to a DPD algorithm where an adaptation algorithm is performed thereon, affects not only DPD performance but also the convergence time of the DPD algorithm due to the gain and phase differences between paths.

The conventional digital predistorter has served to equalize gain and phase differences between two paths without a separate equalizer. That is, the conventional digital predistorter performs both the equalizing function between the two paths and the function of removing a non-linear component of the power amplifier, causing a considerable delay in its convergence time.

### SUMMARY OF THE INVENTION

It is, therefore, an object of the present invention to provide a predistortion apparatus and method for maximizing the performance of a digital predistortion algorithm to generate a linearized output signal when amplifying an output signal of a transmission stage through a non-linear amplifier in a mobile communication system.

It is another object of the present invention to provide a predistortion apparatus and method for reducing the convergence time for digital predistortion by compensating for gain and phase differences between an output signal of a digital predistorter and a feedback signal thereto.

It is further another object of the present invention to provide a predistortion apparatus and method for accurately predistorting an input signal for a short calculation time using a one-tap equalizer.

According to one aspect of the present invention, there is provided a method for compensating for a non-linear characteristic of a wideband power amplifier in a transmitter for a communication system, which comprises the wideband power amplifier for amplifying a digital input signal, the method comprising the steps of (a) generating an address based on the digital input signal, reading a distortion control value corresponding to the address from a look-up table, and applying the read distortion control value to the digital input signal to predistort the digital input signal; (b) frequency up-converting the predistorted signal and amplifying the frequency up-converted signal; (c) frequency down-converting the amplified signal and compensating for a delay of the frequency down-converted signal; and (d) updating a predetermined distortion control value in the look-up table to compensate for an error value generated in the power amplifier and an analog path occurring in steps (b) and (c) based on the compensated signal.

Preferably, the updating step comprises the steps of calculating an output signal of an one-tap equalizer such that a difference between a transmission signal output through the predistorter and a feedback signal output from the wideband power amplifier becomes zero; and calculating a coefficient for the predistorter by performing a predistortion adaptation algorithm on an output signal of the one-tap equalizer and outputting an adaptation result.

According to another aspect of the present invention, there is provided an apparatus for compensating for a non-linear characteristic of a wideband power amplifier in a transmitter for a communication system, which comprises the wideband power amplifier for amplifying a digital input signal, the apparatus including a digital predistorter for determining an address based on the digital input signal and applying a distortion control value corresponding to the address to the digital input signal to predistort the digital input signal; and a digital signal processor for calculating and updating the distortion control value using a transmission signal and a feedback signal to compensate for non-linear distortion occurring on a path for the feedback signal output from the wideband power amplifier.

According to another further aspect of the present invention, there is provided a method for predistorting an output signal of a transmitter in a mobile communication system, the method comprising the steps of calculating intensity of a digital input signal, and determining an address of a look-up table to read a distortion control value corresponding to the digital input signal in the determined address; reading a distortion control value corresponding to the address from the look-up table and applying the read distortion control value to the digital input signal to predistort the digital input signal; frequency up-converting the predistorted signal and amplifying the frequency up-converted signal; calculating a specific coefficient such that a difference between a predistorted transmission output signal and a feedback signal acquired through the amplification becomes zero; updating the look-up table considering the coefficient; and predistorting the digital input signal using the updated look-up table.

According to still another aspect of the present invention, there is provided a transmission apparatus in a mobile communication system. The transmission apparatus comprises a digital predistorter for reading a distortion control value corresponding to a digital input signal from a look-up table, and generating a transmission signal by applying the read distortion control value to the digital input signal; a frequency up-converter for frequency up-converting an output signal of the digital predistorter; a power amplifier for amplifying power of the frequency up-converted signal; and a digital signal processor for measuring an error value generated in a path of a feedback signal from the power amplifier, and updating the distortion control value using the error value.

### BRIEF DESCRIPTION OF THE DRAWINGS

The above and other objects, features and advantages of the present invention will become more apparent from the following detailed description when taken in conjunction with the accompanying drawings in which:

FIG. 1 is a block diagram illustrating a structure for implementing a digital predistortion (DPD) algorithm according to an embodiment of the present invention;

FIG. 2 is a flowchart illustrating a predistortion (PD) adaptation operation of a digital signal processor performed before execution of a DPD algorithm according to an embodiment of the present invention;

FIGS. 3A and 3B are graphs illustrating simulation performance results of an equalizer for a transmission signal to which a random phase error is applied according to an embodiment of the present invention;

FIGS. 4A to 4C are graphs illustrating simulation results on an equalizer for a transmission signal to which a random gain error is applied according to an embodiment of the present invention;

FIG. 5A is a graph illustrating a simulation result of DPD performance for a digital predistorter to which a phase error is applied according to an embodiment of the present invention; and

FIG. 5B is a graph illustrating a simulation result of DPD performance for the case where convergence is achieved for a long time without compensating for a phase error using an equalizer in the case of the 90°-phase error of FIG. 5A.

### DETAILED DESCRIPTION OF AN EXEMPLARY EMBODIMENT

An exemplary embodiment of the present invention will now be described in detail with reference to the annexed drawings. In the following description, a detailed description of known functions and configurations incorporated herein has been omitted for conciseness.

The present invention aims at removing a spurious component generated when amplifying an output signal of a transmission stage in a wideband mobile communication system, and provides an adaptive algorithm that can be simply implemented with a field programmable gate array (FPGA) or a digital signaling processor (DSP) in a high data rate environment. The term “adaptive algorithm” refers to a method of reducing a specific error in an initial value, and in particular, to a method of searching for an optimal value while continuously updating the initial value.

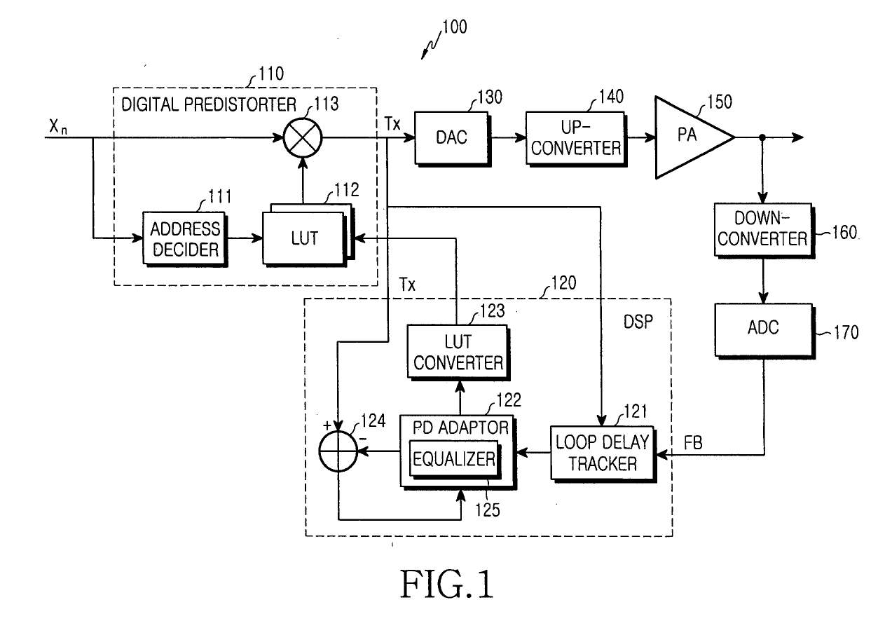

FIG. 1 is a block diagram illustrating a structure for implementing a digital predistortion (DPD) algorithm according to an embodiment of the present invention. Referring to FIG. 1, a transmitter 100 comprises a digital predistorter 110 for estimating a non-linear characteristic of a power amplifier 150 and a digital signal processor 120. The digital predistorter 110 is connected to the power amplifier 150 via a digital-to-analog converter (DAC) 130 and a frequency up-converter 140. The power amplifier 150 is connected to the digital signal processor 120 via a frequency down-converter 160 and an analog-to-digital converter (ADC) 170.

The digital predistorter 110 comprises an address decider 111, a look-up table (LUT) 112 or other storage device or method and a multiplier 113. The address decider 111 calculates intensity of a digital input signal Xn, and determines an address of the look-up table 112, to read a distortion control value corresponding to the calculated intensity of the digital input signal in the determined address. The look-up table 112, after receiving a feedback signal from the digital signal processor 120, outputs a distortion control value corresponding to the determined address. The look-up table 112 stores distortion control values corresponding to all possible intensities of an input signal according to the non-linear characteristic of the power amplifier 150. Herein, the look-up table 112 stores either a predetermined value, such as ‘1’, or a default value determined by a manufacturer, and is comprised of a plurality of constituent look-up tables. The multiplier 113 applies the distortion control value provided from the look-up table 112 to the digital input signal Xn, and outputs the result to the DAC 130.

The digital signal processor 120 comprises a loop delay tracker 121, a predistortion (PD) adaptor 122, an LUT converter 123 and a subtractor 124. The loop delay tracker 121 connected to the PD adaptor 122, compensates for a time delay of a feedback signal from the ADC 170. The PD adaptor 122 preferably comprises therein an equalizer 125 serving as a one-tap equalizer. Although the equalizer 125 is set herein such that it performs equalization only once at the initial stage, the equalizer 125 can also be set such that it performs equalization several times at the initial stage. Alternatively, the equalizer 125 can be arranged outside the PD adaptor 122.

The LUT converter 123 connected to the PD adaptor 122, converts a result value determined by an adaptive algorithm into a format of the digital data stored in the look-up table 112, and provides the converted value to the look-up table 112 for updating thereof That is, the LUT converter 123 initially including information on an inverse function for the power amplifier 150, updates the look-up table 112 using data received from the PD adaptor 122 (for example, a compensation value for the power amplifier 150 and an analog path). The subtractor 124 subtracts an output signal of the equalizer 125 from the predistorted transmission signal Tx output from the digital predistorter 110, and outputs the result to the PD adaptor 122. Herein, the subtraction result value is applied to an error value in an adaptive algorithm used in the PD adaptor 122.

The digital signal processor 120 preferably uses a Least Mean Square (LMS) scheme. Herein, the LMS scheme calculates a coefficient for minimizing an error, converts the coefficient into the form of digital data, for instance, in the form of a table, to be stored in the look-up table 112, and applies the digital data to the digital input signal on the transmission path.

An operation of the transmitter will now be described in more detail below. Referring to FIG. 1, upon receiving a digital input signal Xn, the address decider 111 calculates, preferably, the intensity of the digital input signal and determines an address of the look-up table 112 according to the intensity of the digital input signal from which a distortion control value is to be read. The intensity of the digital input signal is calculated by individually squaring an in-phase (I) signal and a quadrature-phase (Q) signal and then summing the squared values (I²+Q²).

The look-up table 112 outputs a distortion control value corresponding to the determined address. Then, the multiplier 113 multiplies the digital input signal Xn by the distortion control value received from the look-up table 112, and outputs a predistorted transmission signal Tx to the DAC 130.

The DAC 130 after receiving the predistorted transmission signal from the multiplier 113 converts the received digital transmission signal into an analog signal and outputs the analog signal to the frequency up-converter 140. The frequency up-converter 140 up-converts a frequency band of the analog transmission signal into a desired carrier frequency band, and outputs the up-converted transmission signal to the power amplifier 150, and the power amplifier 150 amplifies the up-converted transmission signal into an amplified transmission signal.

At the same time, the frequency down-converter 160 receiving the amplified transmission signal output from the power amplifier 150, down-converts a frequency band of the received transmission signal into an intermediate frequency (IF) band, and the ADC 170 converts the down-converted analog signal into a digital signal and outputs the converted digital feedback signal to the digital signal processor 120.

The loop delay tracker 121 in the digital signal processor 120 calculates a time delay occurring between the predistorted transmission signal Tx output from the digital predistorter 110 and the feedback signal FB, and compensates for the time delay. In an initialization process, the equalizer 125 in the PD adaptor 122 calculates an optimal coefficient such that a difference between the Tx and FB signals received before predistortion should be zero (0), by appropriately controlling an adaptation step size and the number of iteration blocks. Although the equalizer 125 is set herein such that it calculates an optimal coefficient by performing equalization only once at the initial stage, the equalizer 125 can also be set such that it calculates an optimal coefficient by performing equalization even at the non-initial stage.

Thereafter, the PD adaptor 122 updates a polynomial coefficient to be shared with the look-up table 112 using an adaptive algorithm and an error compensation value for an analog path provided from the equalizer 125, and applies the calculated polynomial coefficient to an input signal using the adaptive algorithm, performing predistortion. The adaptive algorithm used herein is preferably an LMS algorithm, and provides a method of searching for an optimal coefficient such that a difference between an output signal value and a target value becomes 0. The adaptive algorithm can be expressed as
w(k+1)=w(k)+μu(k)e*(k) Equation (1)

Equation (1) shows a polynomial coefficient calculated in the PD adaptor 122, and the polynomial becomes an inverse function of a non-linear power amplifier. In Equation (1), w(k) denotes a polynomial coefficient, u(k) denotes a signal input to the PD adaptor 122, and e(k) denotes an error value determined by subtracting an output value of the PD adaptor 122 from an output value of the digital predistorter 110. In addition, μ denotes a convergence coefficient which is less than 1, and * denotes conjugation. The equalizer 125 (e.g., a one-tap equalizer) corresponds to the case where the w(k) in Equation (1) has one coefficientor one tap, and a process of calculating the coefficient will now be described below in more detail.

The LUT converter 123, which receives the distorted signal, converts the received distorted signal into an LUT format using a polynomial coefficient converged in the PD adaptor 122, and outputs the LUT-conversion result to the look-up table 112, for updating thereof. Then the look-up table 112 outputs updated distortion control values corresponding to an address determined by the address decider 111.

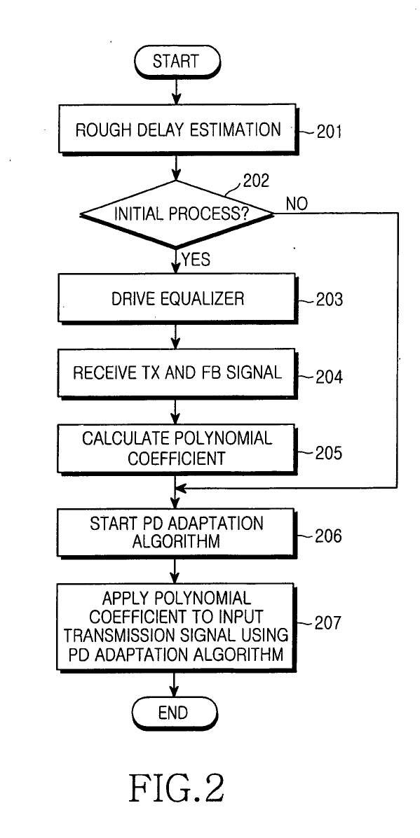

With reference to FIG. 2, a description will now be made of a PD adaptation operation of the digital signal processor 120 performed before execution of a DPD algorithm.

FIG. 2 is a flowchart illustrating a PD adaptation operation of a digital signal processor performed before execution of a DPD algorithm according to an embodiment of the present invention. Referring to FIG. 2, in step 201, a loop delay tracker 121 in a digital signal processor 120 calculates a delay between a predistorted transmission signal Tx received from a digital predistorter 110 and a feedback signal FB received from an ADC 170 using a rough delay estimation algorithm.

In step 202, the digital signal processor 120 determines whether there is a previous input signal, such as whether a current process is an initial process. If the current process is an initial process, the digital signal processor 120 drives an equalizer 125 in step 203. Otherwise, the digital signal processor 120 jumps to step 206 where it immediately performs a PD adaptation algorithm on the delay value using a PD adaptor 122 without driving the equalizer 125.

In step 204, the equalizer 125 receives a transmission signal Tx from a subtractor 124 and a delay-compensated feedback signal FB from the loop delay tracker 121. In step 205, the equalizer 125 calculates gain and phase differences between the Tx and FB signals, in other words, a polynomial coefficient, through the equalizer 125.

The PD adaptor 122 starts the PD adaptation algorithm in step 206, and, in step 207, applies the polynomial coefficient to a predistorted transmission signal Tx using the PD adaptation algorithm to predistort the transmission signal.

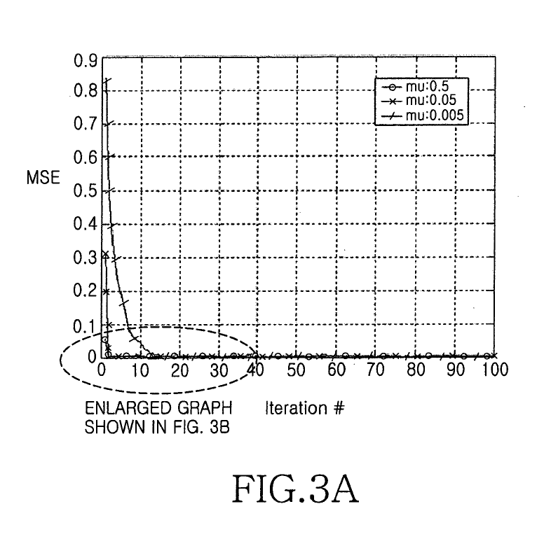

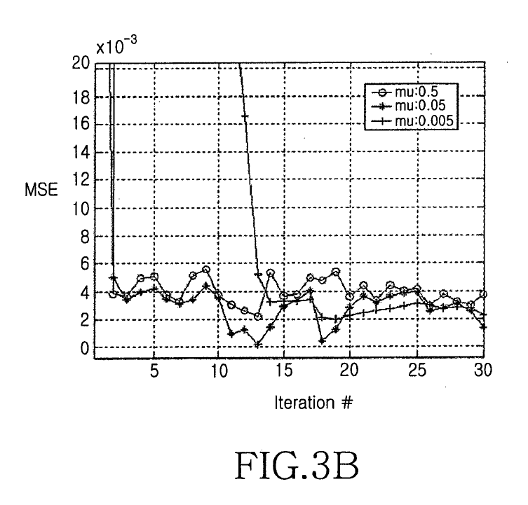

FIGS. 3A and 3B are graphs illustrating simulation performance results of an equalizer for a transmission signal to which a random phase error is applied according to an embodiment of the present invention. In the graphs, a y-axis represents a mean square error (MSE) and an x-axis represents the number of iterations. Herein, one iteration interval includes 700 samples used for convergence of a one-tap equalizer.

The graphs illustrate simulation performance results of a one-tap equalizer 125 acquired by applying a 45° -phase error to a random transmission signal, and show a variation in MSE according to a μ (mu) value. In the graphs, the μ value corresponds to an adaptation step size. According to the simulation results, at a greater μ value, the MSE is minimized at higher speed but the variance is large. However, at a lesser μ value, the MSE is minimized at lower speed but the variance is small.

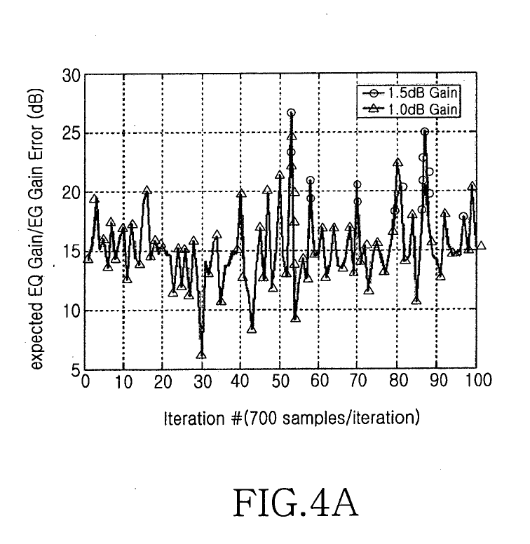

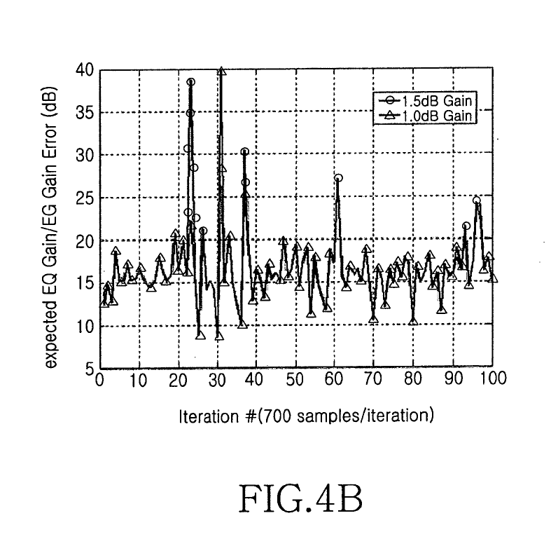

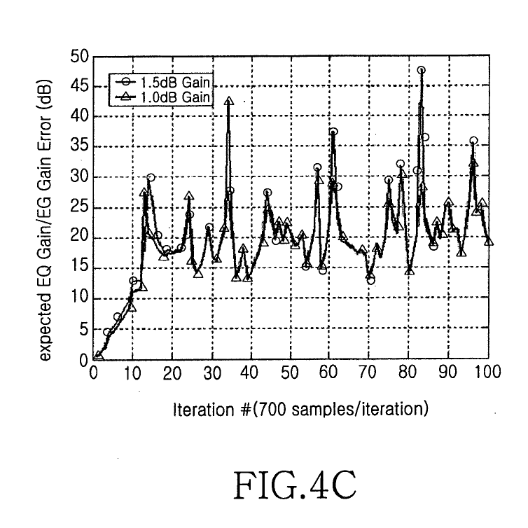

FIGS. 4A to 4C are graphs illustrating simulation performance results of an equalizer for a transmission signal to which a random gain error is applied according to an embodiment of the present invention. In the graphs, the x-axis represents the number of iterations and the y-axis represents a ratio [dB] of an expected equalizer gain to an equalizer gain error.

The graphs of FIGS. 4A to 4C illustrate simulation performance results of an equalizer acquired by applying gain differences of 1 dB and 1.5 dB to Tx and FB signals. FIG. 4A illustrates the simulation result for μ=0.5, FIG. 4B for μ=0.05, and FIG. 4C for μ=0.005.

According to the simulation results, because the equalizer operation is stabilized faster as the μ value increases higher as described with reference to FIGS. 3A and 3B, it can be noted that a y-axis value indicative of the ratio of an expected equalizer gain to an equalizer gain error increases as it goes from FIG. 4A to FIG. 4C.

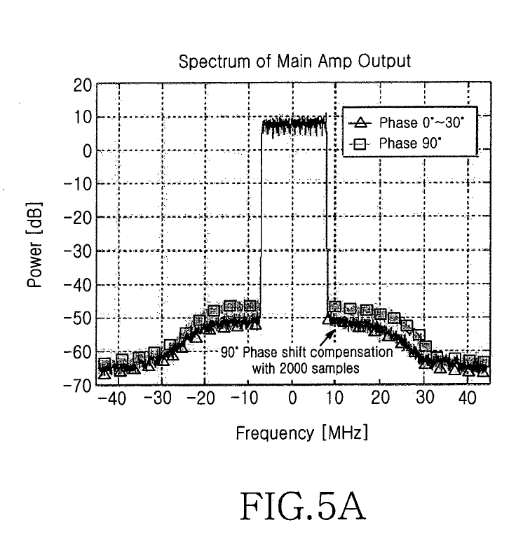

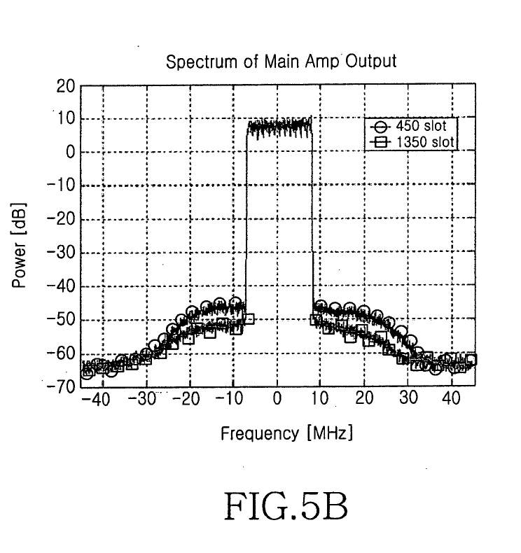

FIG. 5A is a graph illustrating a simulation result on DPD performance for a digital predistorter to which a phase error is applied according to an embodiment of the present invention. In this graph, an x-axis represents a frequency [MHz] and a y-axis represents power [dB]. A line with squares is to represent a capacity in case that a phase error is 90° , and a line with triangles is to represent a capacity in case that a phase error is from 0° to 30°.

It can be understood from FIG. 5A that a 0 to 30°-phase error does not affect system performance but a 90°-phase error causes performance degradation of about 4˜5 dB. A spectrum (represented by a dashed line with squares) shows a simulation result for the 90°-phase error, and the line with triangles, shows a simulation result on DPD performance after the 90°-phase error underwent distortion compensation in an analog path using an embodiment of the equalizer of the present invention at the initial stage. It can be noted herein that because the phase error underwent compensation by the equalizer, the phase error-compensated DPD performance is equal to DPD performance for the case where no error is applied.

FIG. 5B is a graph illustrating a simulation result on DPD performance for the case where convergence is achieved for a long time without compensating for a phase error using an equalizer in the case of the 90°-phase error of FIG. 5A. The graph shows a convergence time required when DPD performance for the case where a phase error is compensated using an equalizer becomes equal to DPD performance for the case where there is no phase error. In this case, because even the DPD adaptation algorithm has a phase error compensation function, the phase error is compensated but a long convergence time is required.

It is noted from FIG. 5B that the case where a phase error is compensated using an equalizer requires 3 times the convergence time required for the case where there is no phase error. A spectrum (represented by a dashed line with circles) shows DPD performance acquired for a 450-slot convergence time without phase-error compensation, and shows performance degradation of about 4 to 5 dB compared with a corresponding spectrum of FIG. 5A. A spectrum (represented by a dashed line with squares) shows DPD performance for the case where the phase error was not compensated, and shows that a 1350-slot convergence time is required when DPD performance for the case where the phase error is not compensated becomes equal to DPD performance for the case where the phase error is compensated using an equalizer.

As can be understood from the simulation performance results, the use of an embodiment of of the present invention reduces the convergence time, contributing to an increase in DPD performance.

As described above, embodiments of the present invention can reduce the time required for reaching optimal performance of a DPD system during operation of the DPD adaptation algorithm, and can apply LUTs designed for a particular power amplifier even to other DPD systems. In this way, it is possible to reduce an initial training time of all DPD systems, thereby contributing to reducing costs.

While the invention has been shown and described with reference to a certain exemplary embodiment thereof, it will be understood by those skilled in the art that various changes in form and details may be made therein without departing from the spirit and scope of the invention as defined by the appended claims.

1. A method for compensating for a non-linear characteristic of a wideband power amplifier in a transmitter for a communication system, which includes the wideband power amplifier for amplifying a digital input signal, the method comprising the steps of:
(a) reading a distortion control value corresponding to an address from a look-up table, and applying the distortion control value to the digital input signal to predistort the digital input signal;
(b) up-converting the frequency of the predistorted signal and amplifying the frequency up-converted signal;
(c) down-converting the frequency of the amplified signal and compensating for a delay of the frequency down-converted signal; and
(d) updating the distortion control value in the look-up table to compensate for an error value generated an analog path occurring in steps (b) and (c) based on the compensated signal.

2. The method of claim 1, wherein the updating step comprises the steps of:
calculating an output signal of an equalizer such that a difference between a transmission signal output through the predistortion and a feedback signal output from the wideband power amplifier becomes zero; and
calculating a coefficient for a predistorter by performing a predistortion adaptation algorithm on an output signal of the equalizer and determining an adaptation result.

3. The method of claim 2, wherein the equalizer is a one-tap equalizer.

4. The method of claim 3, wherein the output signal of the one-tap equalizer is generated using the following equation,
w(k+1)=w(k)+μu(k)e*(k)
where w(k) denotes one element, u(k) denotes a signal input to a predistortion adaptor, e(k) denotes an error value determined by subtracting an output value of the equalizer from an output value of a digital predistorter, μ denotes a convergence coefficient, and * denotes conjugation.

5. The method of claim 3, wherein the coefficient is defined by w(k) in the following equation,
w(k+1)=w(k)+μu(k)e*(k)
where w(k) denotes a polynomial coefficient, u(k) denotes a signal input to a predistortion adaptor, e(k) denotes an error value determined by subtracting an output value of the predistortion adaptor from an outp ut value of a digital predistorter, μ denotes a convergence coefficient, and * denotes conjugation.

6. The method of claim 2, further comprising the step of converting the adaptation result into a look-up table format to update the look-up table.

7. An apparatus for compensating for a non-linear characteristic of a wideband power amplifier in a transmitter for a communication system, comprising the wideband power amplifier for amplifying a digital input signal, the apparatus comprising:
a digital predistorter for applying a distortion control value corresponding to a address to the digital input signal to predistort the digital input signal; and
a digital signal processor for calculating and updating the distortion control value using a transmission signal and a feedback signal to compensate for non-linear distortion of a signal output from the wideband power amplifier.

8. The apparatus of claim 7, wherein the digital predistorter comprises:
a look-up table for outputting the distortion control value corresponding to a address; and
a multiplier for applying the distortion control value to the digital input signal to generate a predistorted transmission signal.

9. The apparatus of claim 7, wherein the digital signal processor comprises:
a loop delay tracker for tracking a delay between a transmission signal output through the digital predistorter and a feedback signal from the wideband power amplifier;
an equalizer for calculating a coefficient such that a difference between the transmission signal and the feedback signal becomes zero; and
a predistortion adaptor for performing a predistortion adaptation algorithm on an output signal of the equalizer, wherein the predistortion adaptor determines an adaptation result.

10. The apparatus of claim 9, wherein the digital signal processor further comprises:
a look-up table for converting the adaptation result into a look-up table format; and
a subtractor for calculating an error value by subtracting a signal output from the predistortion adaptor from the transmission signal, and outputting the error value to the predistortion adaptor.

11. The apparatus of claim 9, wherein the coefficient is a one-tap coefficient and the coefficient is defined by w(k) in the following equation,
w(k+1)=w(k)+μu(k)e*(k)
where w(k) denotes one element, u(k) denotes a signal input to a predistortion adaptor, e(k) denotes an error value determined by subtracting an output value of the equalizer from an output value of a digital predistorter, μ denotes a convergence coefficient, and * denotes conjugation.

12. The apparatus of claim 9, wherein the predistortion adaptor uses the following equation to update the coefficient,
w(k+1)=w(k)+μu(k)e*(k)
where w(k) denotes a polynomial coefficient, u(k) denotes a signal input to a predistortion adaptor, e(k) denotes an error value determined by subtracting an output value of the predistortion adaptor from an output value of a digital predistorter, μ denotes a convergence coefficient, and * denotes conjugation.

13. A method for predistorting an output signal of a transmitter in a mobile communication system, the method comprising the steps of:
calculating an intensity of a digital input signal, and determining an address of a look-up table to read a distortion control value corresponding to the digital input signal in the determined address;
reading a distortion control value corresponding to the address from the look-up table and applying the read distortion control value to the digital input signal to predistort the digital input signal;
up-converting the frequency of the predistorted signal and amplifying the frequency up-converted signal;
calculating a specific coefficient such that a difference between a predistorted transmission output signal and a feedback signal acquired through the amplification becomes zero;
updating the look-up table considering the coefficient; and
predistorting the digital input signal using the updated look-up table.

14. The method of claim 13, wherein the specific coefficient is defined by w(k) in the following equation,
w(k+1)=w(k)+μu(k)e*(k)
where w(k) denotes a polynomial coefficient, u(k) denotes a signal input to a predistortion adaptor, e(k) denotes an error value determined by subtracting an output value of the predistortion adaptor from an output value of a digital predistorter, μ denotes a convergence coefficient, and * denotes conjugation.

15. A transmission apparatus in a mobile communication system, comprising:
a digital predistorter for reading a distortion control value corresponding to a digital input signal from a look-up table, and generating a transmission signal by applying the read distortion control value to the digital input signal;
a frequency up-converter for frequency up-converting an output signal of the digital predistorter;
a power amplifier for amplifying power of the frequency up-converted signal; and
a digital signal processor for measuring an error value generated in a path of a feedback signal from the power amplifier, and updating the distortion control value using the error value.

16. The transmission apparatus of claim 15, wherein the digital predistorter comprises:
an address decider for determining an address of a look-up table to read a distortion control value corresponding to the digital input signal;
a look-up table for outputting a distortion control value corresponding to the determined address; and
a multiplier for generating a predistorted transmission signal by applying the distortion control value to the digital input signal.

17. The transmission apparatus of claim 15, wherein the digital signal processor comprises:
a loop delay tracker for tracking a delay between a predistorted transmission output signal and a feedback signal output from the wideband power amplifier;
an equalizer for calculating a specific coefficient such that a difference between the transmission signal and the feedback signal becomes zero; and
a predistortion adaptor for performing a predistortion adaptation algorithm on the specific coefficient and determining an adaptation result.

18. The transmission apparatus of claim 17, wherein the digital signal processor further comprises:
a look-up table for converting the adaptation result into a look-up table format; and
a subtractor for calculating an error by subtracting a signal output from the predistortion adaptor from the transmission signal, and outputting the error to the predistortion adaptor.

19. The apparatus of claim 15, wherein the specific coefficient is defined by w(k) in the following equation,
w(k+1)=w(k)+μu(k)e*(k)
where w(k) denotes a polynomial coefficient, u(k) denotes a signal input to a predistortion adaptor, e(k) denotes an error value determined by subtracting an output value of the predistortion adaptor from an output value of a digital predistorter, μ denotes a convergence coefficient, and * denotes conjugation.
